(19) United States
(12) Patent Application Publication
(10) Pub. No.: US 2018/0274101 A1
(43) Pub. Date: Sep. 27, 2018

(54) ATOMIC LAYER DEPOSITION APPARATUS AND ATOMIC LAYER DEPOSITION METHOD

(71) Applicant: TOPPAN PRINTING CO., LTD., Tokyo (JP)

(72) Inventor: Mitsuru KANO, Tokyo (JP)

(73) Assignee: TOPPAN PRINTING CO., LTD., Tokyo (JP)

(21) Appl. No.: 15/985,306

(22) Filed: May 21, 2018

Related U.S. Application Data
(63) Continuation of application No. PCT/JP2016/086181, filed on Dec. 6, 2016.

(30) Foreign Application Priority Data
Dec. 7, 2015 (JP) 2015-238671

(51) Int. Cl. C23C 16/54; C23C 16/455

(52) U.S. Cl. CPC C23C 16/54; C23C 16/45544; H01L 51/0097; H01L 2251/5338; H01L 2251/303

(57) ABSTRACT

An atomic layer deposition apparatus for forming an atomic layer on a flexible substrate, the apparatus including an unwinding chamber having an unwinding roll for unwinding the flexible substrate, a winding chamber having a winding roll for winding the flexible substrate on which the atomic layer is formed, a plurality of reaction chambers provided between the unwinding chamber and the winding chamber so that the flexible substrate can pass therethrough, a first supply part for storing a gas containing a first precursor, a first supply pipe connected to the first supply part, a second supply part for storing a purge gas, a second supply pipe connected to the second supply part, a third supply part for storing a gas containing a second precursor, a third supply pipe connected to the third supply part, and an exhaust pipe connected to the plurality of reaction chambers.

### CROSS-REFERENCE TO RELATED PATENT APPLICATIONS

This application is a continuation application filed under 35 U.S.C. § 111(a) claiming the benefit under 35 U.S.C. §§ 120 and 365(c) of International Application No. PCT/JP2016/086181, filed on Dec. 6, 2016, which is based upon and claims the benefit of priority to Japan Patent Application No. 2015-238671, filed on Dec. 7, 2015, the disclosures of which are all hereby incorporated herein by reference in their entireties.

### TECHNICAL FIELD

The present invention relates to an atomic layer deposition apparatus using atomic layer deposition (ALD), and also relates to an atomic layer deposition method. More specifically, the present invention relates to an atomic layer deposition apparatus that continuously forms a thin film formed from an atomic layer by ALD on a flexible substrate that can be wound, and also relates to an atomic layer deposition method.

### BACKGROUND ART

ALD is used for high dielectric constant (high-k) materials and insulating layers for semiconductors as a method that can form a fine thin film having no pinholes along the shape of a substrate surface.

Commercialization of organic light emitting diodes (OLED) into displays and lighting has recently been started, and the use of them for smartphones, etc., has started. These OLED displays use glass substrates, and in terms of avoiding damage to displays due to dropping, and ensuring weight saving and portability, there has been a demand for the development of OLED displays and OLED lighting using flexible substrates made of polymers, etc. However, materials used for OLED displays and OLED lighting are susceptible to degradation by moisture and oxygen, and thus are required to have the ability to block moisture and gas. Specifically, a moisture permeability of 10⁻⁶ g/m²/day or less is desired.

PTL 1 discloses that aluminum oxide formed by ALD is effective as a gas barrier layer used for OLED, and that ALD is a promising production method that realizes high gas barrier properties for OLED.

The basic process of ALD will be described. In the first step, a first gaseous precursor is supplied to a substrate that is allowed to stand in a reaction vessel, and the first precursor is adsorbed to saturation (chemically adsorbed) on the substrate. Subsequently, in the second step, a purge gas is introduced into the reaction vessel, and the excess first precursor (physically adsorbed first precursor) on the substrate surface is removed. Subsequently, in the third step, a second gaseous precursor is introduced into the reaction vessel, and the first precursor adsorbed to saturation on the surface is allowed to react with the second precursor to form a desired material for forming an atomic layer. Subsequently, in the fourth step, a purge gas is introduced again into the reaction vessel, and the excess second precursor on the substrate surface is removed. These four steps typically constitute one cycle, which is a basic unit of ALD. In ALD, the above cycle is repeated for a desired number of times depending on, for example, the thickness of the thin film to be formed.

ALD that changes gases in the reaction vessel explained above is disclosed, for example, in PTL 2 and NPL 1, and is also called temporal ALD (hereinafter also referred to as “TALD”). In each step of ALD, the appropriate exposure conditions (the partial pressure of the precursor, the exposure time, the temperature of the substrate, etc.) are determined depending on the material of the substrate, the composition of the precursor, and their reactivity. In TALD, the vapor pressure of a precursor gas is controlled by controlling the temperature of a precursor container that stores the precursor gas to be supplied to a reaction vessel, and the temperature of a pipe that connects the precursor container and the reaction vessel. The flow rate of the precursor gas is controlled by using a mass flow meter, etc. The exposure time is controlled by using a high-speed valve that opens and closes a pipe for supplying the gas to the reaction vessel. According to TALD, a high-quality thin film having no pinholes can be formed by adjusting the exposure conditions within an appropriate range.

Although high-quality thin films can be formed by TALD, one cycle generally requires several tens of seconds to several minutes; thus, there is a room for improvement in the throughput.

Regarding the improvement in the throughput, spatial ALD (hereinafter also referred to as “SALD”) has recently attracted attention, which performs each step while sequentially moving a substrate in spaces with different gas atmospheres.

In SALD, a first step is performed by allowing a substrate to reside in a gas atmosphere space of a first precursor for a predetermined time. Next, a second step is performed by moving the substrate to a purge gas atmosphere space. Then, a third step is performed by moving the substrate to a gas atmosphere space of a second precursor. Finally, a fourth step is performed by moving the substrate to a purge gas atmosphere space; then, the single cycle described above is completed.

Since SALD allows a plurality of substrates to be placed in each of the above spaces, ALD of a plurality of substrates can proceed at the same time; as a result, an improvement in the throughput can be expected.

PTL 3 discloses an apparatus for forming a thin film by SALD on a flexible substrate made of metal foil, polymer, fiber, etc. According to the apparatus disclosed in PTL 3, SALD is carried out while allowing the flexible substrate to pass several times through a first precursor zone and a second precursor zone that are divided by a purge zone.

[Citation List] [Patent Literature] [PTL 1] JP 2007-516347 A; [PTL 2] U.S. Pat. No. 4,058,430 B; [PTL 3] U.S. Pat. No. 8,137,464 B. [Non-Patent Literature] [NPL 1] Paul Poodt et al., J Vac Sci Technol, A30 (1), 010802, January/February 2012; [NPL 2] J. C. Spagnola et al., J Mater Chem, 20, 4213-4222, 2010; [NPL 3] R. P. Padbury et al., J Vac Sci Technol, A33 (1), 01A112, January/February 2015.

### SUMMARY OF THE INVENTION

### Technical Problem

The appropriate exposure conditions are different in each step of ALD. Further, it has been revealed that the exposure conditions vary depending on the substrate and precursor used, and that even when the same precursor and substrate are used, the exposure conditions vary depending on the growth step of the thin film to be formed, and the crystallinity of the substrate.

In particular, it is known that when a polymer film is used as a flexible substrate, a first precursor infiltrates into the substrate at the initial stage of ALD. NPL 2 discloses that in TALD using trimethylaluminum (TMA) as a precursor, when the material of a polymer substrate to which TMA is adsorbed is changed, the amount of adsorption and the dependency of the number of cycles vary.

NPL 3 discloses that when TMA is adsorbed on a substrate made of polyethylene terephthalate (PET), bulk infiltration proceeds in an amorphous form. This suggests that when the crystallinity of substrates varies, infiltration into the substrates varies even when the materials of the substrates are the same, and that consequently, the adsorption behavior of the precursor also varies.

In consideration of NPL 2 and NPL 3, when a thin film is formed by ALD on a polymer film, it is assumed that the exposure conditions suitable for the initial growth stage and the regular growth stage (two-dimensional growth stage) are different.

However, the first precursor zone in the apparatus for performing SALD disclosed in PTL 3 is a single space; thus, from a structural viewpoint, the flow rate and partial pressure of gas cannot be changed for each cycle. Moreover, the exposure time is determined by the length of the substrate transport passage and the substrate transport speed in the reaction chamber that performs each step. In general, the transport speed is adjusted in conformity with a step in which the exposure time is the longest.

It is therefore not easy to set the exposure conditions to be optimal for each step.

In consideration of the above circumstances, an object of the present invention is to provide an atomic layer deposition apparatus and an atomic layer deposition method, whereby the exposure conditions in each step of ALD can be easily controlled.

### Solution to Problem

An atomic layer deposition apparatus according to a first aspect of the present invention is an atomic layer deposition apparatus for forming an atomic layer on a flexible substrate by atomic layer deposition, the atomic layer deposition apparatus including an unwinding chamber having an unwinding roll for unwinding the flexible substrate, a winding chamber having a winding roll for winding the flexible substrate on which the atomic layer is formed, a plurality of reaction chambers provided between the unwinding chamber and the winding chamber so that the flexible substrate can pass therethrough, a first supply part for storing a gas containing a first precursor, a first supply pipe connected to the first supply part, a second supply part for storing a purge gas, a second supply pipe connected to the second supply part, a third supply part for storing a gas containing a second precursor, a third supply pipe connected to the third supply part, and an exhaust pipe connected to the plurality of reaction chambers, wherein at least one of the first supply pipe, the second supply pipe, and the third supply pipe is connected to each of the plurality of reaction chambers, and at least two of the first supply pipe, the second supply pipe, and the third supply pipe are connected to at least one of the plurality of reaction chambers, and are configured to control the gas type and gas conditions in the reaction chambers.

In the first aspect, the first supply pipe, the second supply pipe, and the third supply pipe may be connected to all of the plurality of reaction chambers, and may be configured to be able to control the gas type and gas conditions in the reaction chambers.

In the first aspect, the atomic layer deposition apparatus may further include a guide roller disposed in at least one of the plurality of reaction chambers, and the flexible substrate may pass through the plurality of reaction chambers while having its transport direction changed by the guide roller.

In the first aspect, the atomic layer deposition apparatus may further include a plasma electrode disposed in at least one of the plurality of reaction chambers.

In the first aspect, the atomic layer deposition apparatus may further include a purge chamber that is connected to the second supply pipe and the exhaust pipe, and arranged to communicate with all of the plurality of reaction chambers.

In the first aspect, at least one of the plurality of reaction chambers may be configured to be detachable and attachable.

An atomic layer deposition apparatus according to a second aspect of the present invention is an atomic layer deposition apparatus for forming an atomic layer on a flexible substrate by atomic layer deposition, the atomic layer deposition apparatus including an unwinding chamber having an unwinding roll for unwinding the flexible substrate, a winding chamber having a winding roll for winding the flexible substrate on which the atomic layer is formed, a plurality of reaction chambers provided between the unwinding chamber and the winding chamber so that the flexible substrate can pass therethrough, a first supply part for storing a gas containing a first precursor, a first supply pipe connected to the first supply part, a second supply part for storing a purge gas containing a second precursor, a second supply pipe connected to the second supply part, and an exhaust pipe connected to the plurality of reaction chambers, wherein at least one of the first supply pipe and the second supply pipe is connected to each of the plurality of reaction chambers, and the first supply pipe and the second supply pipe are connected to at least one of the plurality of reaction chambers, while a plasma electrode is disposed therein, and are configured to control the gas type and gas conditions in the reaction chambers.

An atomic layer deposition apparatus according to a third aspect of the present invention is an atomic layer deposition apparatus for forming an atomic layer on a flexible substrate by atomic layer deposition, the atomic layer deposition apparatus including an unwinding chamber having an unwinding roll for unwinding the flexible substrate, a winding chamber having a winding roll for winding the flexible substrate on which the atomic layer is formed, a plurality of reaction chambers provided between the unwinding chamber and the winding chamber so that the flexible substrate can pass therethrough, a first supply part for storing a gas containing a first precursor A, a first supply pipe connected to the first supply part, a second supply part for storing a purge gas, a second supply pipe connected to the second supply part, a third supply part for storing a gas containing a second precursor, a third supply pipe connected to the third supply part, a fourth supply part for storing a gas containing a first precursor B, a fourth supply pipe connected to the fourth supply part, and an exhaust pipe connected to the plurality of reaction chambers, wherein at least one of the first supply pipe, the second supply pipe, the third supply pipe, and the fourth supply pipe is connected to each of the plurality of reaction chambers, and at least two of the first supply pipe, the second supply pipe, the third supply pipe, and the fourth supply pipe are connected to at least one of the plurality of reaction chambers, and are configured to control the gas type and gas conditions in the reaction chambers.

An atomic layer deposition method according to a fourth aspect of the present invention is an atomic layer deposition method for forming an atomic layer on a flexible substrate by spatial atomic layer deposition, wherein an exposure amount of a first precursor to the flexible substrate in a first cycle is larger than the exposure amount thereof in a second cycle that is performed after the first cycle.

### Advantageous Object of the Invention

The atomic layer deposition apparatuses and the atomic layer deposition method according to the above aspects of the present invention allow for easier control of the exposure conditions in each step of ALD.

### BRIEF DESCRIPTION OF THE DRAWINGS

FIG. 1A schematic diagram showing the internal structure of an atomic layer deposition apparatus according to a first embodiment of the present invention.

FIG. 2 A schematic diagram showing the internal structure of the atomic layer deposition apparatus according to the first embodiment of the present invention viewed from a direction different from that of FIG. 1.

FIG. 3 A functional block diagram of the atomic layer deposition apparatus according to the first embodiment of the present invention.

FIG. 4 A diagram which illustrates an example of the gas conditions in the respective reaction chambers.

FIG. 5 A diagram which illustrates an example of the gas conditions in the respective reaction chambers.

FIG. 6 A schematic diagram showing the internal structure of an atomic layer deposition apparatus according to a second embodiment of the present invention.

FIG. 7 A schematic diagram showing the internal structure of a modified example of the atomic layer deposition apparatus according to the second embodiment of the present invention.

FIG. 8 A table showing an example of setting of the reaction chambers in the atomic layer deposition apparatus according to the first and second embodiments of the present invention.

FIG. 9 A table showing another example of setting of the reaction chambers.

FIG. 10 A table showing another example of setting of the reaction chambers.

FIG. 11 A table showing another example of setting of the reaction chambers.

FIG. 12 A schematic diagram showing the inside of reaction chambers in a modified example of the atomic layer deposition apparatus according to the first and second embodiments of the present invention.

FIG. 13 A schematic diagram showing the inside of reaction chambers in another modified example.

FIG. 14 A schematic diagram showing the internal structure of a modified example of the atomic layer deposition apparatus according to the first and second embodiments of the present invention.

### DESCRIPTION OF REPRESENTATIVE EMBODIMENTS

However, it will be understood that the present invention is not limited to these embodiments. These embodiments are intended to be representative of the present invention.

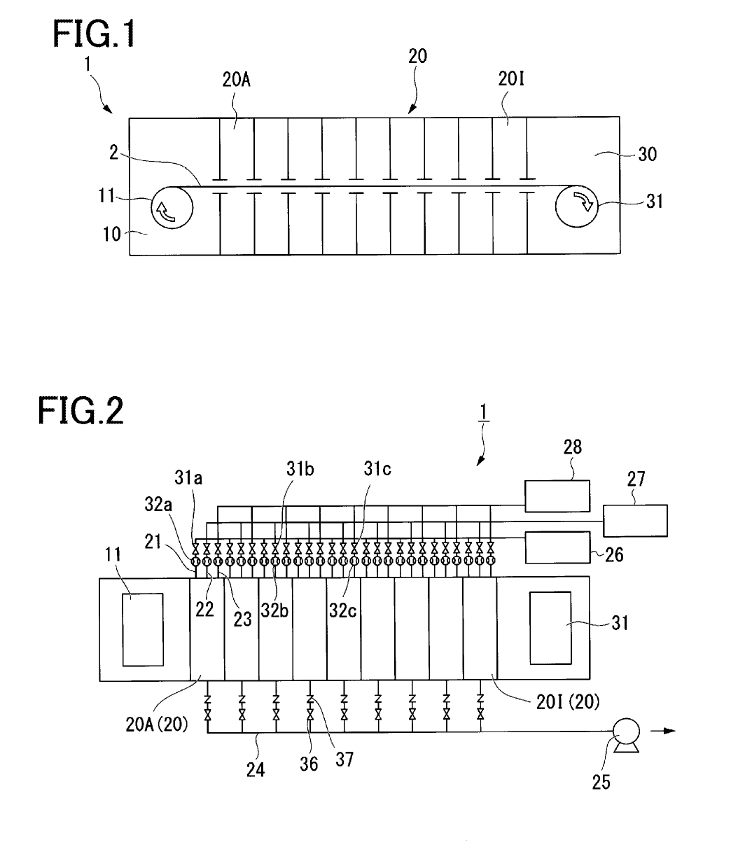

With reference to FIGS. 1 to 5, a first embodiment of the present invention will be described. FIG. 1 is a schematic diagram showing the internal structure of an atomic layer deposition apparatus 1 according to the present embodiment viewed from a lateral side. The atomic layer deposition apparatus 1 forms a thin film by depositing an atomic layer by SALD on the surface of a flexible substrate 2 using a roll-to-roll (RTR) technique.

The atomic layer deposition apparatus 1 includes an unwinding chamber 10, a winding chamber 30, and a plurality of reaction chambers 20. The flexible substrate 2 is fed out from the unwinding chamber 10. The flexible substrate 2 on which an atomic layer is deposited is wound in the winding chamber 30. The plurality of reaction chambers 20 is arranged between the unwinding chamber 10 and the winding chamber 30.

The unwinding chamber 10 includes an unwinding roll (unwinding member) 11. The unwinding roll 11 feeds out the flexible substrate 2. The flexible substrate 2, which is a target for formation of an atomic layer, is wound in a roll shape around the unwinding roll 11. As the unwinding roll 11 rotates, the flexible substrate 2 is fed out to the reaction chamber 20.

The winding chamber 30 includes a winding roll (winding member) 31. The winding roll 31 winds the flexible substrate 2 on which the atomic layer is deposited. As the winding roll 31 rotates, the flexible substrate 2 coming out from the reaction chamber 20 is wound by the winding roll 31.

The unwinding roll 11 and the winding roll 31 are driven to rotate synchronously so that slack, etc., do not occur in the flexible substrate 2. A driving source for driving rotation (not shown) may be provided in one of the unwinding roll 11 and the winding roll 31, or may be provided in both of them.

The reaction chambers 20 are provided in plural numbers so that the steps in one cycle of ALD can be performed by SALD. In the present embodiment, as shown in FIG. 1, nine reaction chambers in total, including a first reaction chamber 20A to a ninth reaction chamber 20I, are arranged in the transport direction of the flexible substrate 2.

FIG. 2 is a schematic diagram showing the internal structure of the atomic layer deposition apparatus 1 viewed from above. As shown in FIG. 2, three supply pipes, i.e., a first supply pipe 21, a second supply pipe 22, and a third supply pipe 23, are connected to each of the reaction chambers 20A to 20I. The first supply pipes 21 connected to the respective reaction chambers are joined in one on the upstream side, and are connected to a first supply part 26. The first supply part 26 stores a gas containing a first precursor (hereinafter also referred to as “first precursor gas”). The second supply pipes 22 connected to the respective reaction chambers are joined in one on the upstream side, and are connected to a second supply part 27. The second supply part 27 stores a purge gas. The third supply pipes 23 connected to the respective reaction chambers are joined in one on the upstream side, and are connected to a third supply part 28. The third supply part 28 stores a gas containing a second precursor (hereinafter also referred to as “second precursor gas”).

Each first supply pipe 21 connected to each reaction chamber has a valve 31a and a mass flow meter 32a. Each valve 31a can be switched between open and closed states. Each mass flow meter 32a is provided between each valve 31a and each reaction chamber. Similarly, each second supply pipe 22 connected to each reaction chamber has a valve 31b and a mass flow meter 32b. Further, each third supply pipe 23 connected to each reaction chamber has a valve 31c and a mass flow meter 32c.

In each of the reaction chambers 20A to 20I, an exhaust pipe 24 is connected to a side surface opposite to the side surface to which the supply pipes are connected. The exhaust pipes 24 connected to the respective reaction chambers are joined in one on the downstream side, and are connected to an exhaust pump 25.

Each exhaust pipe 24 connected to each reaction chamber has a valve 36 and a variable conductance valve 37. Each valve 36 can be switched between open and closed states. Each variable conductance valve 37 is provided between each valve 36 and each reaction chamber.

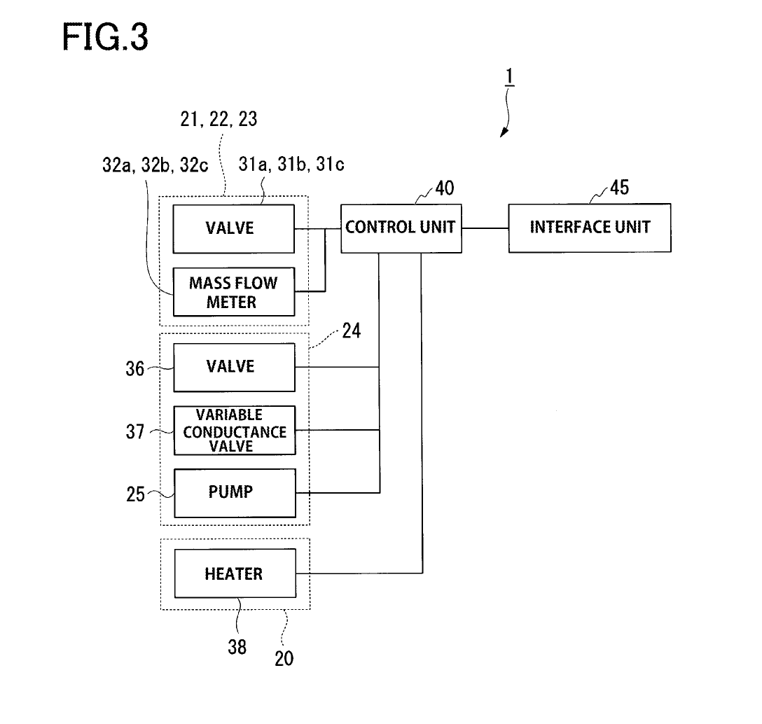

FIG. 3 is a functional block diagram of the atomic layer deposition apparatus 1. The atomic layer deposition apparatus 1 includes a control unit 40 and an interface unit 45. The control unit 40 controls the entire apparatus. The interface unit 45 is connected to the control unit 40.

The control unit 40 is connected to the valves 31a to 31c, the mass flow meters 32a to 32c, the valve 36, and the variable conductance valve 37, which are disposed in each of the reaction chambers 20A to 20I. The control unit 40 is configured to be able to independently control the opening and closing of each valve, and the opening degree thereof.

Moreover, a heater 38 is attached to each of the reaction chambers 20A to 20I. Each heater 38 is connected to the control unit 40. Accordingly, the control unit 40 is configured to be able to independently control the internal temperature of each reaction chamber. Further, the pump 25 for the exhaust pipes is also connected to the control unit 40.

The operation of the atomic layer deposition apparatus 1 of the present embodiment during use, which is configured as described above, will now be explained.

As a preparation process, a roll of the flexible substrate 2 is attached to the unwinding roll 11, and one end of the roll is made to advance into the reaction chamber 20A and sequentially pass through the reaction chambers 20A to 20I. Then, the one end coming out from the reaction chamber 20I is attached to the winding roll 31.

The material of the flexible substrate 2 is suitably determined depending on the laminate to be produced, and examples thereof include polyethylene terephthalate (PET) and the like.

Next, the precursor gases and the purge gas used in each of the supply parts 26 to 28 are prepared. For example, when atomic layer deposition of aluminum oxide is performed, for example, trimethylaluminum (TMA) and nitrogen can be used as the first precursor and the purge gas, respectively, and H₂O can be used as the second precursor gas. When TMA and H₂O are used as the precursors, sufficient gas pressure can be generally obtained in the supply parts even at room temperature.

Next, a user sets the atomic layer deposition apparatus 1 using the interface unit 45 to input, into the control unit 40, the types of precursor gas and purge gas used, the temperature of each reaction chamber, the type of gas introduced, the gas conditions such as partial pressure and flow rate, the transport speed of the flexible substrate 2, and the like. This setting input may be omitted when the type, conditions, etc., of the precursor gas and the purge gas used are already provided to the control unit 40 because, for example, they are fixed or the same as those in the previous operation.

When the setting is completed, the control unit 40 first activates the pump 25 to evacuate each reaction chamber, thereby forming a vacuum state. Subsequently, the heaters 38 are suitably operated to adjust the temperature condition of each of the reaction chambers 20A to 20I within the predetermined range. Known feedback control, etc., may be used for the temperature control.

The temperature of each reaction chamber is selected in consideration of the heat resistance of the flexible substrate 2, the reactivity of the precursors, the heat resistance (thermal decomposition temperature) of the precursors, and the like. For example, when the material of the flexible substrate 2 is PET, the heat-resistant temperature is 120° C. or less; thus, the temperature of each reaction chamber is set to around 100° C. Even when the temperature of each reaction chamber is 100° C., the reaction of ALD using TMA and H₂O proceeds.

Subsequently, the control unit 40 controls the opening and closing of the valves and variable conductance valves connected to the respective reaction chambers, and adjusts the internal state of each reaction chamber based on the setting.

When the first precursor gas or the second precursor gas is supplied to a reaction chamber, the control unit 40 opens, for example, the corresponding valve 31a or 31c. In this state, while referring to the value of the corresponding mass flow meter 32a or 32c, the exhaust rate is adjusted by controlling the valve 36 and the variable conductance valve 37 of the corresponding exhaust pipe 24. The inside of the reaction chamber is thereby filled with the desired precursor gas, and the gas conditions of the precursor gas are adjusted within the set range.

When the purge gas is supplied to a reaction chamber, the control unit 40 opens, for example, the corresponding valves 31b and 36. In this state, while referring to the value of the corresponding mass flow meter 32b, the exhaust rate is adjusted by controlling the variable conductance valve 37 of the corresponding exhaust pipe 24, whereby the inside of the reaction chamber is filled with the purge gas, and the gas conditions of the purge gas are adjusted within the set range.

Due to the control of the control unit 40 described above, each of the reaction chambers 20A to 20I is adjusted to optimal exposure conditions in the assigned step of ALD. In this state, the flexible substrate 2 is transported from the unwinding chamber 10 to the winding chamber 30 at the predetermined desired rate. Each step of SALD is thereby performed on the flexible substrate 2. Consequently, an atomic layer made of a desired material is deposited on the flexible substrate 2. After the atomic layer deposition is completed, the flexible substrate 2 is sequentially wound by the winding roll 31.

In the atomic layer deposition apparatus 1 according to the present embodiment, each of the plurality of reaction chambers 20A to 20I includes the first supply pipe 21, the second supply pipe 22, and the third supply pipe 23. This makes it possible to use each reaction chamber as a reaction space of the first precursor or the second precursor, and to use each reaction chamber as a space for purging. Accordingly, the atomic layer deposition apparatus 1 can suitably correspond to combinations of various precursors and cycle configurations; thus, a highly versatile apparatus can be formed.

Further, the supply pipes 21 to 23 provided in each reaction chamber are provided with, respectively, the valves 31a to 31c and the mass flow meters 32a to 32c. Moreover, each exhaust pipe 24 is provided with the valve 36 and the variable conductance valve 37. The control unit 40 is thereby configured to be able to independently set the gas conditions in each reaction chamber. As a result, for example, the reaction chambers to which the same gas is introduced can be adjusted to different gas conditions by changing the partial pressure, flow rate, etc., depending on, for example, the number of cycles that have been performed. Consequently, the exposure conditions of each step in SALD can be easily controlled, and film formation by ALD can be preferably performed.

Furthermore, the atomic layer deposition apparatus 1 is advantageous in that the time to perform each step can be easily adjusted.

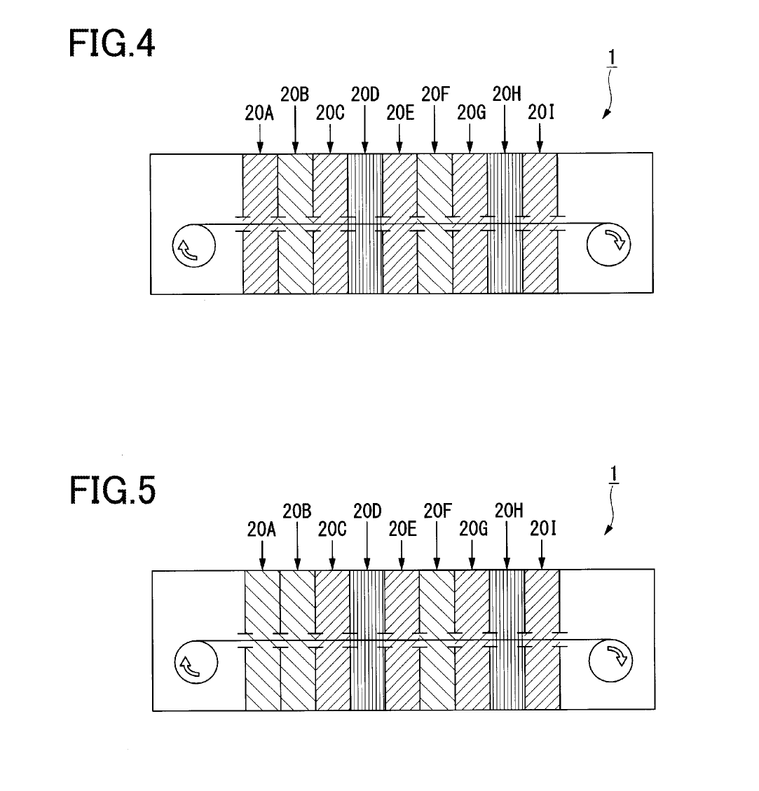

In the example shown in FIG. 4, the purge gas is supplied to the reaction chambers 20A, 20C, 20E, 20G, and 20I, the first precursor gas is supplied to the reaction chambers 20B and 20F, and the second precursor gas is supplied to the reaction chambers 20D and 20H. This results in a configuration in which two cycles of ALD are performed by one transport operation. In FIG. 4, the gases supplied to the reaction chambers are expressed as patterns.

In the state shown in FIG. 4, for example, when the gas supplied to the reaction chamber 20A is changed to the first precursor gas, the configuration of the reaction chambers is as shown in FIG. 5. In the configuration shown in FIG. 5, two cycles are performed by one transport operation, as in FIG. 4; however, the reaction step of the first precursor in the first cycle is carried out for a time twice as long as that of the configuration of FIG. 4. Thus, the atomic layer deposition apparatus 1 allows, not only the gas conditions to vary for each reaction chamber, but also the exposure time of each step to be easily controlled.

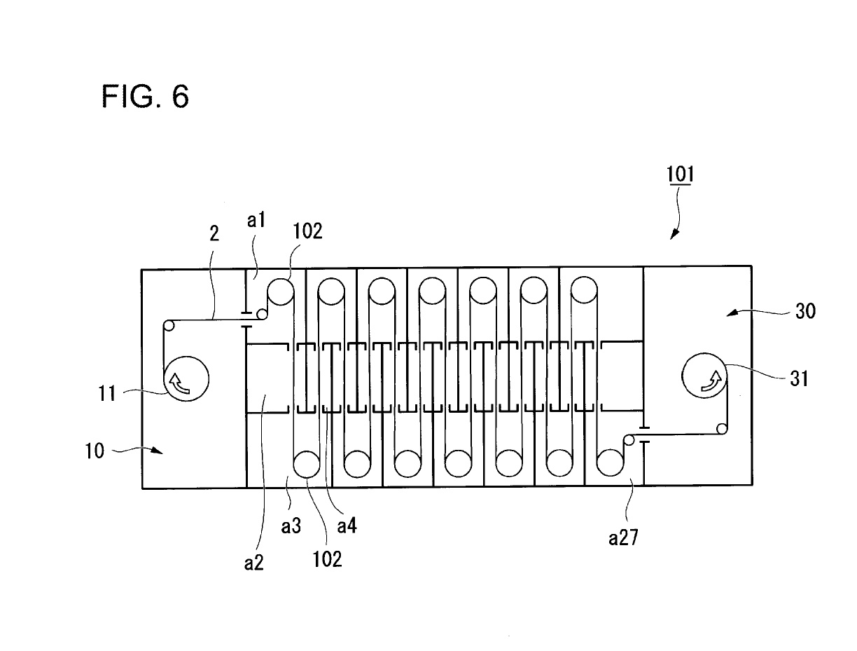

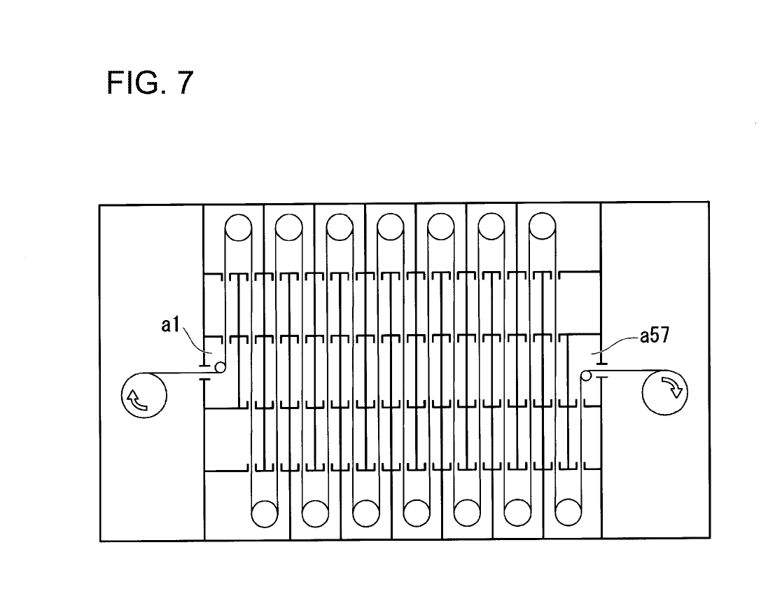

Next, with reference to FIGS. 6 and 7, the second embodiment of the present invention will be described. The atomic layer deposition apparatus according to the present embodiment differs from the atomic layer deposition apparatus 1 of the first embodiment in the arrangement of a plurality of reaction chambers. In the following explanation, the same reference signs are assigned to structures common in those already explained above, and the duplicated description is omitted.

FIG. 6 is a schematic diagram showing the internal structure of an atomic layer deposition apparatus 101 according to the present embodiment viewed from a lateral side. In the atomic layer deposition apparatus 101 according to the present embodiment, a plurality of reaction chambers is repeatedly arranged in the vertical direction, as shown in FIG. 6. More specifically, a flexible substrate 2 unwound from an unwinding roll 11 first enters a reaction chamber a1 provided on the upper side of the apparatus. The direction of the flexible substrate 2 entering the reaction chamber a1 is changed by a guide roller 102, and the flexible substrate 2 is moved to a reaction chamber a2 located below the reaction chamber a1. Thereafter, the flexible substrate 2 enters a reaction chamber a3 located below the reaction chamber a2, its direction is changed by a guide roller 102 in the reaction chamber a3, and the flexible substrate 2 heads toward an upper reaction chamber a4.

Thus, the flexible substrate 2 is moved toward the winding chamber 30 passing through the reaction chambers, while being repeatedly transported upward and downward by the guide rollers 102. In order to minimize the influence on the formed atomic layer, each guide roller 102 is placed so as to be in contact with only both ends of the flexible substrate 2 in the width direction, which is perpendicular to the transport direction.

Although not shown in FIG. 6 for simplicity reasons, all the reaction chambers, including the reaction chamber a1 that communicates with the unwinding chamber 10 to the reaction chamber a27 that communicates with the winding chamber 30, each include three supply pipes 21 to 23 each provided with a valve and a mass flow meter, and an exhaust pipe 24 provided with a valve and a variable conductance valve. Further, although not shown, the atomic layer deposition apparatus 101 includes a control unit 40 and an interface unit 45 as with the first embodiment.

In the atomic layer deposition apparatus 101 according to the present embodiment, the exposure conditions of each step in SALD can also be easily adjusted, as in the atomic layer deposition apparatus 1 according to the first embodiment.

Moreover, because each of the plurality of reaction chambers includes the guide roller 102, even when the reaction chambers are arranged in a zigzag order in the vertical direction, SALD can be carried out while preferably allowing the flexible substrate 2 to pass through the reaction chambers by appropriately changing the transport direction of the flexible substrate 2. Furthermore, an increase in the size of the apparatus can be prevented.

In the present embodiment, reaction chambers positioned in the upstream and downstream sides of one reaction chamber are positioned above or below. Accordingly, it is highly possible that a gas supplied to a certain reaction chamber enter other communicating reaction chambers due to the difference in specific gravity, etc. In order to appropriately prevent this possibility, the control unit 40 may be set so that the internal pressure of the reaction chamber to which the purge gas is supplied is higher than the internal pressure of the reaction chambers to which the first precursor gas and the second precursor gas are supplied. Alternatively, the communication passages of the reaction chambers may be provided with flap-like entrance prevention parts for preventing the movement of gas between the reaction chambers. Furthermore, the internal pressure control mentioned above and the entrance prevention parts may be used in combination.

Such gas entrance preventive measures may also be carried out in the first embodiment in which the flexible substrate is transported horizontally.

Moreover, as in the modified example shown in FIG. 7, three or more reaction chambers may be arranged in the vertical direction to form a structure including more reaction chambers al to a57. In FIG. 7, five reaction chambers are arranged in the vertical direction; however, the number of reaction chambers arranged in the vertical direction may be, for example, two, four, or other even number.

The following explains, using a plurality of examples, an embodiment of SALD using the atomic layer deposition apparatus according to the above embodiment of the present invention, and setting of each reaction chamber for performing the SALD.

### Setting Example 1

Setting Example 1 is an example of forming an atomic layer made of aluminum oxide on a flexible PET substrate by plasma ALD using the atomic layer deposition apparatus 101.

In Setting Example 1, TMA, nitrogen, and oxygen are used as a first precursor, a purge gas, and a second precursor, respectively.

Among a plurality of reaction chambers a1 to a27, TMA is introduced into each of the reaction chambers a1, a5, a9, a13, a17, a21, and a25. Oxygen is introduced into each of the reaction chambers a3, a7, all, a15, a19, a23, and a27. Plasma electrodes, not shown, are previously disposed in the reaction chambers into which oxygen is introduced, and oxygen plasma is generated before the start of SALD. The plasma electrodes may be previously disposed in all of the reaction chambers, and only the plasma electrodes in the reaction chambers to which oxygen is supplied may be energized.

Nitrogen is introduced into each of the rest reaction chambers a2, a4, a6, a8, a10, a12, a14, a16, a18, a20, a22, a24, and a26.

When the flexible substrate 2 is fed out from the winding chamber in this state, TMA is first chemically adsorbed on the surface of the flexible substrate 2 in the reaction chamber a1. Subsequently, in the reaction chamber a2, TMA physically adsorbed on the flexible substrate 2 is removed from the flexible substrate 2 by nitrogen, which is the purge gas. Further, in the reaction chamber a3, TMA chemically adsorbed on the flexible substrate 2 is exposed to oxygen plasma, and an atomic layer of aluminum oxide is formed by deposition. When excess oxygen is removed in the reaction chamber a4, one cycle of SALD is completed. Then, the same process is repeated, and seven cycles of SALD are carried out on the flexible substrate 2 before the flexible substrate 2 reaches the winding chamber 30.

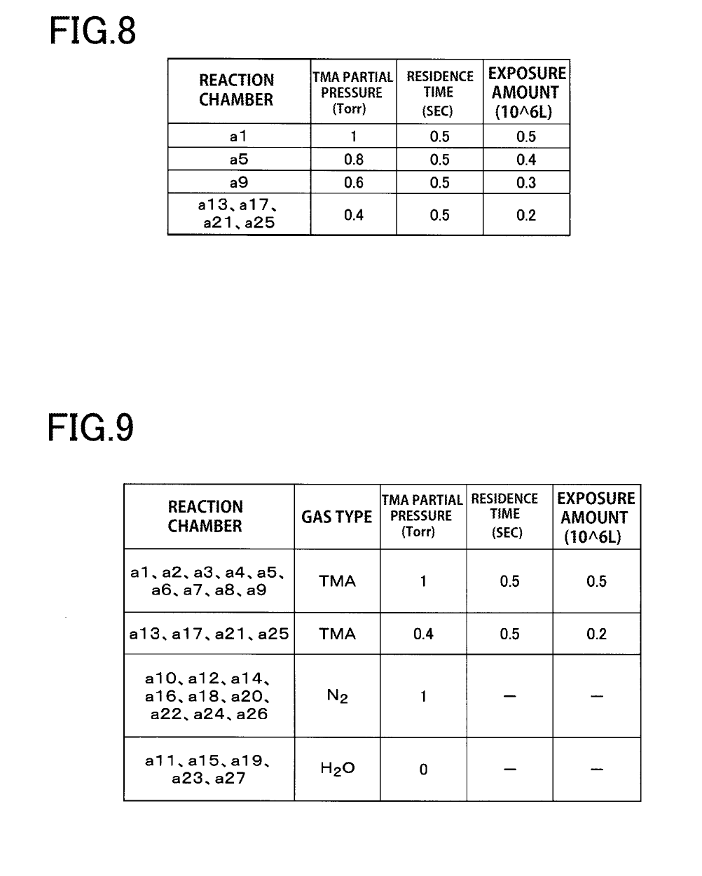

FIG. 8 is a table showing an example in which the gas conditions of the first precursor gas are changed for each reaction chamber in Setting Example 1. In the example shown in FIG. 8, the partial pressure of TMA is set to be the highest in the reaction chamber a1 of the first cycle, and the partial pressure is set to gradually decrease in the second and subsequent cycles. Since the transport distance (e.g., 0.3 meter (m)) and transport speed (e.g., 36 m/s) of the flexible substrate 2 are constant in each reaction chamber, the residence time of the flexible substrate 2 in each reaction chamber is the same. Therefore, the exposure amount (Langmuir (L)) represented by the product of partial pressure and residence time is set to be the highest in the reaction chamber a1, to decrease as the cycles progress, and to be constant in the fourth and subsequent cycles.

The atomic layer deposition apparatus according to the present embodiment can also easily perform such control.

### Setting Example 2

Setting Example 2 is an example of changing the time required for each step in some of the reaction chambers to which the first precursor is supplied. The first precursor and the purge gas are the same as those of Setting Example 1, and H₂O is used as the second precursor gas.

FIG. 9 is a table showing an example of setting of each reaction chamber in Setting Example 2. In the example shown in FIG. 9, a first precursor gas containing TMA as the first precursor is supplied to nine reaction chambers, i.e., the reaction chambers a1 to a9, which are connected to the unwinding chamber 10. Accordingly, the time of the chemical adsorption step of the first precursor in the first cycle is 0.5×9=4.5 seconds. The chemical adsorption steps in the second and subsequent cycles are performed using one reaction chamber under conditions in which the partial pressure is lower than that of the first cycle.

In the examples shown in FIGS. 8 and 9, the exposure amount of TMA in the first cycle is set to be larger than those in the second and subsequent cycles, thereby increasing the amount of TMA infiltrating into the flexible substrate 2, and also increasing the amount of TMA adsorbed thereon. As a result, TMA is reliably adsorbed to saturation on the surface of the flexible substrate, and a fine layer can be formed in the interface between the substrate and the atomic layer.

### Setting Example 3

Setting Example 3 is an example of forming an atomic layer made of mixed oxide on a flexible PET substrate using the atomic layer deposition apparatus 101. In this example, two types of first precursors, i.e., TMA and titanium chloride (IV, TiCl₄), are used. A mixed gas (N₂+CO₂) of nitrogen and carbon dioxide is used as the purge gas, and oxygen is used as the second precursor. That is, in this example, the purge gas contains the second precursor, and the second precursor is in a state made reactive by production of plasma.

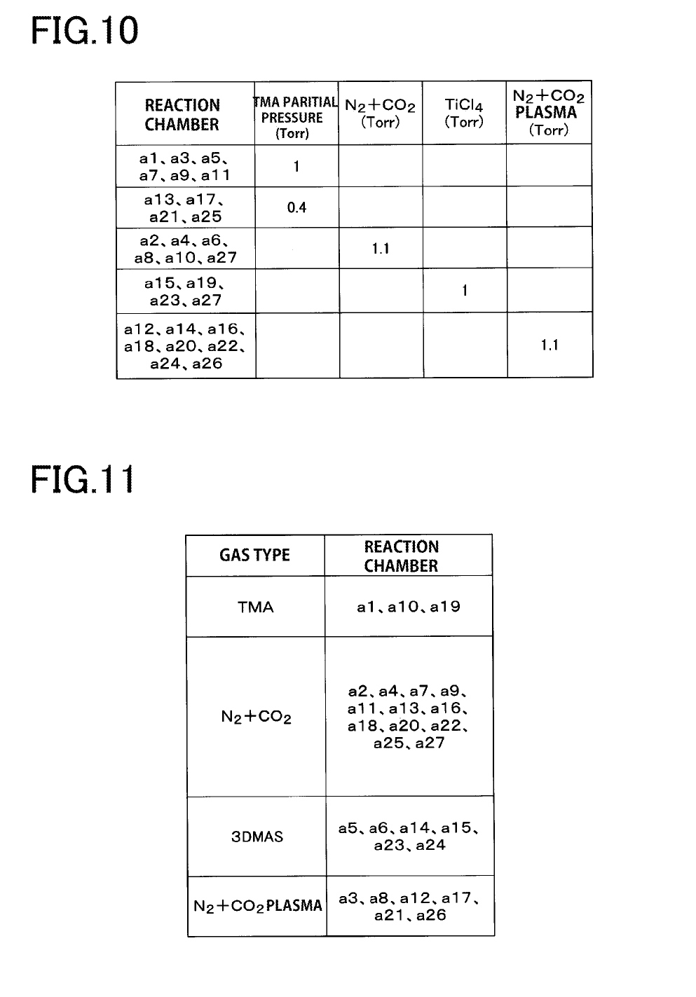

FIG. 10 is a table showing an example of setting of each reaction chamber in Setting Example 3. In the example shown in FIG. 10, the flexible substrate 2 is first repeatedly moved in the reaction chambers of the first precursor and the purge reaction chambers to promote the infiltration and adsorption of TMA (reaction chambers a1 to a10). Thereafter, the flexible substrate 2 is sequentially moved to the reaction chamber of the first precursor gas (TMA), the reaction chamber of the purge gas, the reaction chamber of the first precursor gas (titanium(IV) chloride), and the reaction chamber of the purge gas. Plasma (N₂+CO₂ plasma) is generated in some of the reaction chambers of the purge gas, thereby performing an oxidation reaction of the first precursor while purging (reaction chambers a1 to a27). The step of purging and oxidation by N₂+CO₂ plasma can be carried out by increasing the size of the reaction chamber rather than the diffusion length of active species (atomic oxygen etc.) from the plasma electrode.

Due to the above setting, an atomic layer made of mixed oxide of aluminum oxide and titanium oxide can be deposited and formed on the flexible substrate 2.

### Setting Example 4

Setting Example 4 is an example of changing one of the first precursors used in Setting Example 3. In this example, tris(dimethylamino)silane (3DMAS) is used in place of titanium(IV) chloride.

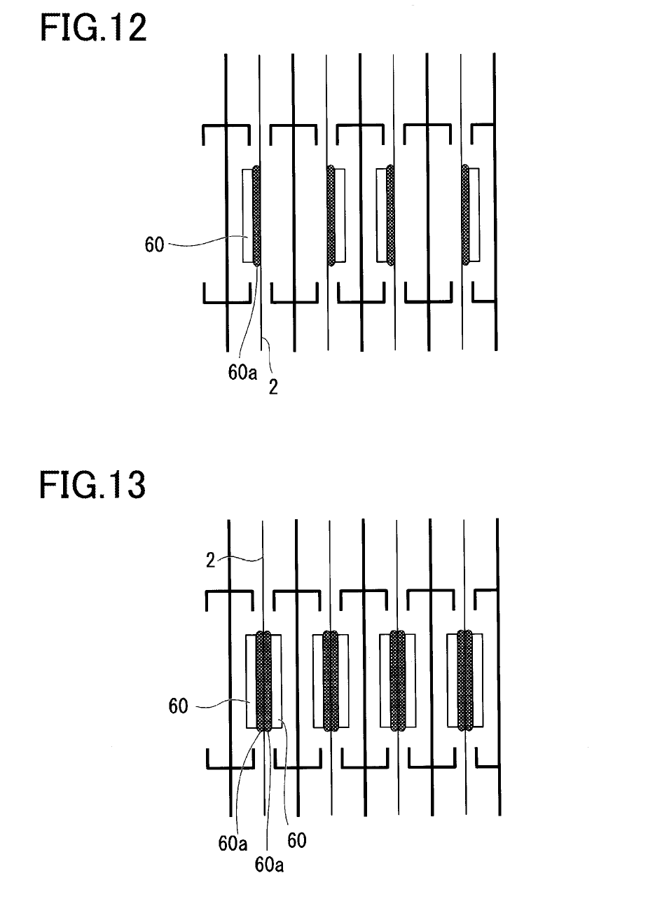

FIG. 11 is a table showing an example of setting of each reaction chamber in Setting Example 4. In the example shown in FIG. 11, a cycle is performed while sequentially moving the flexible substrate 2 through the first precursor gas (TMA), the purge gas (N₂+CO₂), purge and oxidation (N₂+CO₂ plasma), the purge gas, the first precursor gas (3DMAS), the purge gas (N₂+CO₂), purge and oxidation (N₂+CO₂ plasma), and the purge gas. Here, two continuous reaction chambers are assigned in the 3DMAS adsorption step.

The exposure amount of 3DMAS required for saturated adsorption is generally larger than that of TMA; that is, 3DMAS requires a longer time for saturated adsorption at the same precursor partial pressure. Because more reaction chambers are assigned to 3DMAS than TMA, as in the example of FIG. 11, SALD using 3DMAS can be carried out without reducing the transport speed of the flexible substrate. In this example, aluminum oxide can be deposited for four cycles and silicon oxide can be deposited for three cycles, using the atomic layer deposition apparatus 101. When an apparatus including a larger number of reaction chambers, as shown in FIG. 7, is used, the number of cycles can be suitably increased.

In Setting Example 4, the oxidation reaction can also be promoted by assigning a plurality of reaction chambers to the step of purging and oxidation of 3DMAS.

Two types of first precursors are used in Setting Examples 3 and 4. Thus, when atomic layer deposition of ternary metal oxide is performed by the atomic layer deposition apparatus of the present invention using two types of first precursors (e.g., a first precursor A and a first precursor B), a fourth supply part and a fourth supply pipe may be provided so that, for example, the first precursor A is stored in the first supply part, and the first precursor B is stored in the fourth supply part. When ALD of a ternary metal oxide is performed, setting may be made so that the purge gas does not contain the second precursor.

The embodiments and setting examples of the present invention are explained above; however, the technical scope of the present invention is not limited to the above embodiments, and it is possible to change the combination of the components, add various modifications to each component, or delete the components, within a range that does not depart from the gist of the present invention.

For example, the above embodiments explain examples in which three supply pipes are provided in all the reaction chambers; however, not all of the plurality of reaction chambers have to include the all supply pipes. In one example, the reaction chamber adjacent to the unwinding chamber may not include the third supply pipe for supplying the second precursor gas. Further, two or more supply pipes may be connected to only some of the plurality of reaction chambers, although the degree of freedom of setting is reduced.

Moreover, the supply pipes of the plurality of reaction chambers are not necessarily connected to a single supply part. Therefore, each supply pipe may receive gas supply from a different supply part.

Moreover, the exhaust pipes are not necessarily provided in all of the reaction chambers, and may be provided only in some reaction chambers. However, in the case of a structure in which a plurality of reaction chambers shares one exhaust pipe, setting is preferably made so as to avoid the possibility that a plurality of precursors is present in the same reaction chamber due to the flow of the gas following discharge.

Furthermore, at least one of the plurality of reaction chambers may be configured to be detachable and attachable to thereby obtain a structure in which SALD can be carried out with minimum required reaction chambers depending on the specific contents, such as cycles and steps. Conversely, additional reaction chamber units that are configured to be detachable and attachable may be provided to obtain a structure that can accommodate an increase in the number of steps or cycles.

For example, in order to form an atomic layer having a thickness of about 10 to 20 nanometers (nm) by ALD, it is generally necessary to perform 100 or more cycles of ALD. Thus, when it is necessary to significantly increase the number of steps or cycles, the unwinding chamber and the winding chamber may be configured to be detachable and attachable, so that the atomic layer deposition apparatuses described above may be connected to each other. In the case of such a structure, when the unwinding chamber and the winding chamber are configured to also include a plurality of supply pipes, the exposure conditions can be set more easily.

As briefly mentioned in the above setting examples, plasma electrodes may be provided in some or all of the plurality of reaction chambers. When plasma active species are used as the second precursor, a plasma electrode 60 is disposed on only one side in the thickness direction of the flexible substrate 2, namely one surface side of the substrate, as shown in FIG. 12. Plasma active species 60a can thereby be concentrated on one surface side of the flexible substrate 2, and atomic layer deposition can be performed on only one side of the flexible substrate 2. When atomic layer deposition is performed on both surfaces of the flexible substrate 2, the plasma electrodes 60 may be disposed on both sides in the thickness direction of the flexible substrate 2, namely both surface sides of the substrate, as shown in FIG. 13,

When SALD is performed only by a structure in which the purge gas contains an element that functions as the second precursor, and plasma active species are used as the second precursor, the atomic layer deposition apparatus of the present invention may have a structure not including a third supply part and a third supply pipe.

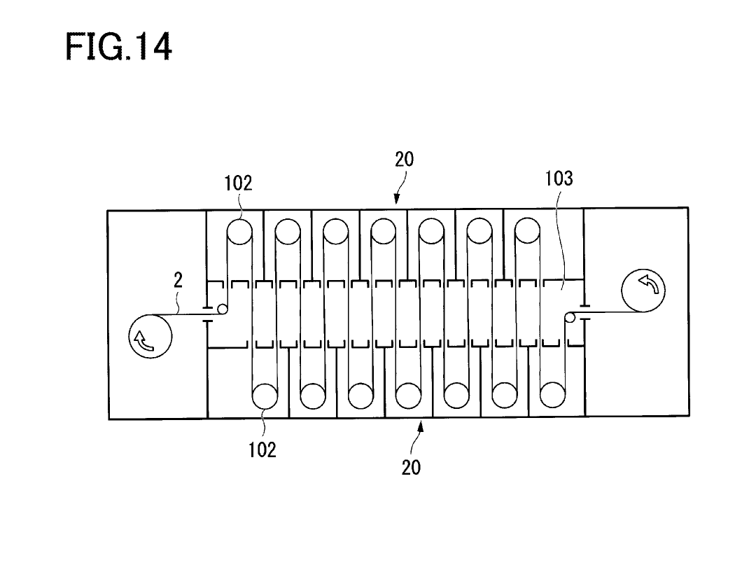

Moreover, as in the modified example shown in FIG. 14, the atomic layer deposition apparatus may also be configured to include a plurality of reaction chambers 20 each provided with a guide roller 102, and a single purge chamber 103 connected to a second supply pipe and an exhaust pipe (not shown) and arranged to communicate with the plurality of reaction chambers 20. This structure can be used without any problem, for example, when the setting of gas conditions for purging is the same, although cycle forms that can correspond to this structure are slightly reduced; and the structure of the apparatus can be simplified.

In this modified example, only the first supply pipe and the third supply pipe may be connected to the plurality of reaction chambers 20, and the purge space may not be used.

Moreover, when a guide roller is provided in each reaction chamber, the guide roller may be movably placed in the reaction chamber. In this case, it is possible to finely regulate the transport distance in each reaction chamber, and it is also possible to make more detailed settings than the setting by assignment of reaction chambers.

In addition to the above, the unwinding chamber may be configured to enable plasma treatment by glow discharge. Moreover, the winding chamber may be configured in such a manner that other layers, such as an overcoat layer, can be formed on the formed atomic layer.

In place of the formation of an overcoat layer, etc., the winding chamber may be configured in such a manner that the substrate is wound around the winding roll after a protective film (inserting paper) is placed on the substrate surface, in order to protect the formed atomic layer thin film.

Furthermore, in the atomic layer deposition apparatus of the present invention, SALD can also be repeatedly performed by configuring the unwinding roll and the winding roll to be reversely rotatable. More specifically, after completion of the delivery from the unwinding roll, resetting is made in such a manner that the settings of the reaction chambers are arranged in the same manner from the winding chamber side. After completion of resetting the exposure conditions, the same SALD can be performed again by moving the flexible substrate from the winding chamber to the unwinding chamber. Here, when each reaction chamber is previously set so that the order from the unwinding chamber side and the order from the winding chamber side are the same, the step of resetting the exposure conditions is not necessary, and SALD can be continuously carried out more efficiently.

[Reference Signs List] 1, 101 . . . Atomic layer deposition apparatus; 2 . . . Flexible substrate; 10 . . . Unwinding chamber; 20, 20A, 20B, 20C, 20D, 20E, 20F, 20G, 20H, 20I . . . Reaction chamber; 21 . . . First supply pipe; 22 . . . Second supply pipe; 23 . . . Third supply pipe; 24 . . . Exhaust pip; 26 . . . First supply part; 27 . . . Second supply part; 28 . . . Third supply part; 30 . . . Winding chamber; 60 . . . Plasma electrode; 102 . . . Guide roller; 103 . . . Purge chamber; a1, a2, a3, a4, a27, a57 . . . Reaction chamber.

What is claimed is:

1. An atomic layer deposition apparatus for forming an atomic layer on a flexible substrate, the apparatus comprising:
an unwinding chamber having an unwinding roll for unwinding the flexible substrate;
a winding chamber having a winding roll for winding the flexible substrate on which the atomic layer is formed;
a plurality of reaction chambers provided between the unwinding chamber and the winding chamber so that the flexible substrate can pass therethrough;
a first supply part for storing a gas containing a first precursor;
a first supply pipe connected to the first supply part;
a second supply part for storing a purge gas;
a second supply pipe connected to the second supply part;
a third supply part for storing a gas containing a second precursor;
a third supply pipe connected to the third supply part; and
an exhaust pipe connected to the plurality of reaction chambers, wherein
at least one of the first supply pipe, the second supply pipe, and the third supply pipe is connected to each of the plurality of reaction chambers, and
at least two of the first supply pipe, the second supply pipe, and the third supply pipe are connected to at least one of the plurality of reaction chambers, and are configured to control the gas type and gas conditions in the reaction chambers.

2. The atomic layer deposition apparatus of claim 1, wherein the first supply pipe, the second supply pipe, and the third supply pipe are connected to all of the plurality of reaction chambers, and configured to be able to control the gas type and gas conditions in the reaction chambers.

3. The atomic layer deposition apparatus of claim 1, further comprising a guide roller disposed in at least one of the plurality of reaction chambers, wherein the flexible substrate passes through the plurality of reaction chambers while having its transport direction changed by the guide roller.

4. The atomic layer deposition apparatus of claim 1, further comprising a plasma electrode disposed in at least one of the plurality of reaction chambers.

5. The atomic layer deposition apparatus of claim 1, further comprising a purge chamber that is connected to the second supply pipe and the exhaust pipe, and arranged to communicate with all of the plurality of reaction chambers.

6. The atomic layer deposition apparatus of claim 1, wherein at least one of the plurality of reaction chambers is configured to be detachable and attachable.

7. An atomic layer deposition apparatus for forming an atomic layer on a flexible substrate by atomic layer deposition, the apparatus comprising:
an unwinding chamber having an unwinding roll for unwinding the flexible substrate;
a winding chamber having a winding roll for winding the flexible substrate on which the atomic layer is formed;
a plurality of reaction chambers provided between the unwinding chamber and the winding chamber so that the flexible substrate can pass therethrough;
a first supply part for storing a gas containing a first precursor;
a first supply pipe connected to the first supply part;
a second supply part for storing a purge gas containing a second precursor;
a second supply pipe connected to the second supply part; and
an exhaust pipe connected to the plurality of reaction chambers, wherein
at least one of the first supply pipe and the second supply pipe is connected to each of the plurality of reaction chambers, and
the first supply pipe and the second supply pipe are connected to at least one of the plurality of reaction chambers, while a plasma electrode is disposed therein, and are configured to control the gas type and gas conditions in the reaction chambers.

8. An atomic layer deposition apparatus for forming an atomic layer on a flexible substrate by atomic layer deposition, the atomic layer deposition apparatus comprising:
an unwinding chamber having an unwinding roll for unwinding the flexible substrate;
a winding chamber having a winding roll for winding the flexible substrate on which the atomic layer is formed;
a plurality of reaction chambers provided between the unwinding chamber and the winding chamber so that the flexible substrate can pass therethrough;
a first supply part for storing a gas containing a first precursor A;
a first supply pipe connected to the first supply part;
a second supply part for storing a purge gas;
a second supply pipe connected to the second supply part;
a third supply part for storing a gas containing a second precursor;
a third supply pipe connected to the third supply part;
a fourth supply part for storing a gas containing a first precursor B;
a fourth supply pipe connected to the fourth supply part; and
an exhaust pipe connected to the plurality of reaction chambers, wherein
at least one of the first supply pipe, the second supply pipe, the third supply pipe, and the fourth supply pipe is connected to each of the plurality of reaction chambers, and
at least two of the first supply pipe, the second supply pipe, the third supply pipe, and the fourth supply pipe are connected to at least one of the plurality of reaction chambers, and are configured to control the gas type and gas conditions in the reaction chambers.

9. An atomic layer deposition method for forming an atomic layer on a flexible substrate by spatial atomic layer deposition, wherein an exposure amount of a first precursor to the flexible substrate in a first cycle is larger than the exposure amount thereof in a second cycle that is performed after the first cycle.
